(19) United States
(12) Patent Application Publication
(10) Pub. No.: US 2024/0280626 A1
(43) Pub. Date: Aug. 22, 2024

(54) Computer-Implemented Method for Optimizing a Detection Threshold of a Prediction Model

(71) Applicant: Robert Bosch GmbH, Stuttgart (DE)

(72) Inventors: Daniel Zander, Oberriexingen (DE); Anton Iakovlev, Boeblingen (DE); Damir Shakirov, Niefern-Oeschelbronn (DE); David Schoenleber, Karlsruhe (DE); Erin Sebastian Schmidt, Heimsheim (DE); Jonas Bergdolt, Bietigheim-Bissingen (DE); Jonathan Levin, Reutlingen (DE); Matthias Werner, Stuttgart (DE); Stefan Patrick Lindt, Ettlingen (DE); Timo Pfrommer, Stuttgart (DE); Uwe Lehmann, Dresden (DE)

(21) Appl. No.: 18/443,912

(22) Filed: Feb. 16, 2024

(30) Foreign Application Priority Data
Feb. 17, 2023 (DE) 10 2023 201 383.5

(51) Int. Cl. G01R 31/26

(52) U.S. Cl. CPC G01R 31/2601

(57) ABSTRACT

A computer-implemented method for optimizing a detection threshold of a prediction model used to determine an anomaly of a component is disclosed. The detection threshold indicates the criterion above which the prediction model classifies a component as anomalous. The method includes (i) providing the prediction model, (ii) providing a plurality of pre-test results determined for a plurality of test parameters for a plurality of components, respectively, (iii) providing a final test result for each of the plurality of components, wherein the respective final test result indicates whether the respective component has an anomaly in a final test, (iv) calculating a respective anomaly result for each of the plurality of components by evaluating the respective pre-test results by the prediction model, (v) calculating a respective explainability value for each of the plurality of test parameters for each of the plurality of components by the prediction model, and (vi) optimizing the detection threshold based on the calculated anomaly results, the calculated explainability values and the final test results provided.

### BACKGROUND

This application claims priority under 35 U.S.C. § 119 to patent application no. DE 10 2023 201 383.5, filed on Feb. 17, 2023 in Germany, the disclosure of which is incorporated herein by reference in its entirety.

The disclosure relates to a computer-implemented method for optimizing a detection threshold of a prediction model used to determine an anomaly of a component, in particular a semiconductor component and/or a chip and/or a wafer.

A semiconductor manufacturing process, also referred to as a chip manufacturing process, includes steps to produce semiconductor components such as transistors, diodes, and integrated circuits (ICs). The process usually starts with the cleaning and preparation of substrates and wafers, mostly from silicon, on which the semiconductor components are created. Thereafter, layers of different materials, such as silicon dioxide and metal, are usually applied to the substrate using techniques such as thermal oxidation, CVD, and sputtering deposition. These layers serve as insulation and conductors for the semiconductor components.

Thereafter, patterns are often applied to the layers using techniques such as lithography and removed by etching to create the circuits and components. The components are then activated by annealing and diffusion. The final step is to create connections between the components and the substrate to establish the electrical connections.

The manufacturing process requires constant precise control of temperatures, pressure and chemical conditions in order to achieve the desired properties of the semiconductor components. Even by altering a single process parameter of the highly complex manufacturing process, chips and/or wafers and/or the resulting semiconductor components may already be defective and thus lead to undesirable production waste. In addition, test conditions may also change over time or changes may also occur in the manufacturing process itself, for example, due to the aging of a manufacturing system. Such changes must be detected as early as possible in order to avoid a corresponding degradation of the semiconductor component. Such changes may also occur in other technical areas apart from semiconductor manufacturing, for example in the manufacture of complex mechanical and/or electrical and/or electronic components.

Therefore, quality control plays a key role in semiconductor manufacturing and the manufacture of other technically complex components. Quality control often involves steps to monitor and/or optimize product quality during the manufacturing process. This includes both visual inspections and measurements of the electrical and/or chemical and/or mechanical properties of the components in question. Quality control also includes monitoring cleanliness and environmental conditions in the manufacturing environment to ensure that no particles or contaminants are introduced to the components. This process is of crucial importance to ensure that the subsequent components have the required properties and desired reliability for the subsequent area of application and that the production yield remains high.

Some of the most important steps in quality control include monitoring process parameters during manufacturing to ensure that process parameters are always within a specified range wherever possible. Furthermore, quality control often includes performing visual inspections, preferably coupled to each manufacturing step, in order to ensure that no visible faults occur in the components to be manufactured, for example chips and/or wafers and/or semiconductor components.

In addition, the electrical properties of the semiconductor components are checked using test processes, such as resistance measurement, conductivity measurement, current-voltage characteristics, and electrical function tests. The resulting measurement results of manufactured components, such as chips or semiconductor components are then compared in the prior art in the course of a final test with reference measurement results, for example, which can be assigned with high-quality components by an expert on the basis of domain knowledge, for example. Individual measurement results are often univariately assessed or evaluated, and compared, for example, with a limit value or a threshold interval derived from the reference measurement results.

The final test determines whether a component in question fulfills its intended function while taking into account a predetermined tolerance value. Faults discovered during the final test often reveal problems along a very long process chain, making it difficult to perform retrospective troubleshooting. In addition, there are often several weeks between a possibly problematic process step and a final test, therefore defective components may have already been produced for weeks by the time the fault is discovered, which leads to a large amount of rejected components, which in turn is associated with a huge monetary loss.

To alleviate this problem, one of the first steps in testing the functionality of a particular component is typically a pre-test that provides test results during component manufacture that provide guidance for the final test. The results of these pre-tests are used as quality control during component manufacturing, so to speak.

Despite this pre-test, production faults and/or component faults in particular, that occur in later phases of manufacturing and that could have been detected in a suitable pre-test are not always correctly detected.

In order to minimize this problem, the use of machine learning algorithms is known, that are used, for example, to classify whether a component is defective or faulty in the course of this pre-test. A variety of machine learning algorithms may be used for anomaly detection. Examples include an Isolation Forest algorithm and/or a reconstruction fault algorithm of a PCA and/or an autoencoder algorithm. The Isolation Forest algorithm is an algorithm for detecting data anomalies that was originally developed in 2008 by Fei Tony Liu and Zhi-Hua Zhou. Such machine learning algorithms can be used as predictors to predict failures in later stages of a manufacturing process, in particular results of a final test of a respective component, already in the course of the pre-test.

Autoencoders are a type of artificial neural networks used to compress and reproduce data. They consist of two main parts: an encoder that transforms the input data into a compressed coding space, and a decoder that reproduces the compressed data back to its original form. There are various types of autoencoders, such as the simple autoencoder, the convolutional autoencoder, the variational autoencoder, and the generative adversarial autoencoder, for example.

Principal Component Analysis (PCA) is a statistical method used to capture and visualize the structure of complex data. It serves to reduce the dimensions of the data without losing important information. PCA is primarily used to transform data into a smaller set of new variables, referred to as principal components, which may have a greater variance than the original variables. Thus, the PCA uses a number of features to be analyzed that is smaller than the number of features originally to be examined, in order to obtain residuals that allow a statement to be made about an anomaly in the semiconductor component to be examined. An inverse PCA may where necessary be used to reconstruct data. Then, it is determined whether and where reconstruction faults are particularly high relative to the initial data in order to draw conclusions about an anomaly.

Although several approaches to anomaly detection for the quality control of components, for example semiconductor components, are known from the prior art, there is still development potential, in particular with regard to predictive accuracy in the classification of a component using an underlying prediction model.

The disclosure is thus based on the task of further developing a method for anomaly detection of a component, in particular a semiconductor component and/or a chip and/or a wafer, in such a way that the above-mentioned disadvantages are at least partially overcome, and in particular an optimized prediction model which is used to determine an anomaly of a component, in particular a semiconductor component and/or a chip and/or a wafer, can be specified.

The task is solved by a computer-implemented method for optimizing a detection threshold of a prediction model according to the features described below. Furthermore, the task is solved by a method for determining an anomaly of a component according to the description below.

### SUMMARY

The disclosure relates to a computer-implemented method for optimizing a detection threshold of a prediction model used to determine an anomaly of a component, in particular a semiconductor component and/or a chip and/or a wafer. The prediction model is preferably used for predicting a component quality during the manufacture of a component in the course of a pre-test evaluation. The detection threshold indicates the criterion, for example the anomaly score and/or explainability value above which the prediction model classifies a component as anomalous. The method comprises the steps of providing the prediction model to be optimized; providing a plurality of pre-test results determined for a plurality of test parameters for a plurality of components, respectively; providing a final test result for each of the plurality of components, wherein the respective final test result indicates whether the respective component has an anomaly in a final test; calculating a respective anomaly result for each of the plurality of components by evaluating the respective pre-test results by the prediction model; calculating a respective explainability value for each of the plurality of test parameters for each of the plurality of components by the prediction model; and optimizing the detection threshold based on the calculated anomaly results, the calculated explainability values and the final test results provided. Pre-tests are preferably tests that are performed before a final test, in order to be able to estimate the subsequent quality of a component during manufacture. According to the present disclosure, it is advantageous, compared to the prior art, to also include the explainability values resulting from the pre-tests in order to improve the predictive capability by optimizing the threshold value of the prediction model.

Detecting a component anomaly is particularly important for highly complex and/or expensive components, in order to minimize rejects as early as possible. The focus here is on assessing whether or not a component meets one or more of the expected quality criteria. In the case of anomaly analysis based on pre-test results, this assessment is preferably performed without having a final measurement result, a so-called ground truth, for the component. According to the present disclosure, it is now proposed to detect anomalies in results from pre-tests, which precede the final test of a component, in order to be able to estimate whether a component or product will pass the subsequent final test or be classified as anomalous or defective. By using pre-tests, resources can be utilized more efficiently and particularly economically during component manufacturing.

In the prior art, however, only the anomaly result obtained by the prediction model for the respective component is used for the anomaly evaluation of the relevant component when analyzing pre-test results. As a result, the failure and/or a substandard quality of the component in question can, in the case of anomaly detection, be predicted based on the pre-test results. However, the known prediction models often also provide an incorrect classification and thus incorrectly classify “normal” or good quality components as anomalous, for example, because the sensitivity of the prediction algorithm is set too high.

Setting or optimizing the detection threshold is comparable to setting the sensitivity of the prediction model. If the detection threshold is too high, for example, components that have an anomaly are also not correctly classified as anomalous in the course of the pre-test phase, so that these components may only be classified as defective in the course of the final test or not at all. Since some time may pass between the manufacture of the respective component and the respective final test, many components may have already been manufactured, especially in the case of sources of error on the manufacturing side, which components are accounted for as rejects or losses from the time the fault is detected. If the detection threshold is selected too low, for example, even components that do not have an anomaly will also be classified as defective or incorrectly classified as normal or OK in the course of the pre-test phase, so these components may be flagged as rejects by the prediction algorithm. This must also be prevented, as otherwise even good components that are suitable for resale will end up as rejects or losses. This is solved by the method according to the disclosure.

According to the present disclosure, the use of the anomaly score and additional explainability values, such as Shapley values, enables a more accurate, in particular optimized, estimation of a fault probability of a component to be examined already in the pre-test phase. This enables a particularly early detection of process problems. The optimized prediction method according to the disclosure provides an indicator of which properties or parameters are responsible for the predicted failures and/or anomalies This results from the fact that the explainability values are also included. According to the disclosure, defective components can be scrapped at an early stage and overall waste is reduced. Furthermore, according to the present disclosure, it is already possible in the pre-test phase to give an expectation or an estimate of which component yield is to be expected in the final test phase. This allows a benchmark to be created for the (manufacturing) processes between the pre-test phase and the final test phase. This plays a role in packaging, for example. If the final test results are available and are associated with the pre-test results according to the disclosure, the following advantages also arise. On the one hand, it is possible to precisely tune a numeric threshold value for detecting anomalies and predicting explainability values. In addition, improved hyper-parameter tuning of the prediction model or anomaly detection algorithm may be performed. This preferably results from using the final test results as the ground truth while maintaining the prediction model for anomaly detection, in particular the unsupervised prediction model. The prediction model can also be further trained based on the method according to the disclosure by means of supervised or at least partially supervised learning.

The explainability value preferably indicates how anomalous the component is if only a certain input value or test parameter is considered. The explainability value preferably indicates the extent to which a particular input value or test parameter contributes to the overall anomaly value. The anomaly result, on the other hand, is preferably determined from an aggregation of the plurality of explainability values. The aggregation is not necessarily purely cumulative.

The anomaly detection according to the disclosure may preferably be used to accelerate the transfer of production lines to new locations and/or to accelerate a root cause analysis during the start-up of a new plant. The method according to the disclosure can be used for almost every industry and many types of components as soon as a suitable data basis is available in the form of pre-test results and final test results. The method according to the disclosure is particularly preferably used in the field of semiconductor manufacturing, but can also be transferred to almost any manufacturing assurance area and/or quality assurance area in which at least one pre-test and/or one intermediate test and/or one final test is/are performed.

It is understood that the steps according to the disclosure and further optional steps do not necessarily have to be carried out in the order shown, but can also be carried out in a different order. Further intermediate steps may also be provided. The individual steps may also comprise one or more sub-steps without leaving the scope of the method according to the disclosure.

In a preferred embodiment, the at least one prediction model comprises a machine learning algorithm, in particular an autoencoder model and/or a PCA model. In principle, further prediction models are also possible, so the list is not to be understood to be exhaustive.

In a preferred embodiment, the optimized detection threshold optimizes a predictive accuracy of the prediction model when detecting an anomaly of a component. This can minimize rejection of components compared to the prior art.

In a preferred embodiment, the pre-test results correlate at least partially and/or by parameter with the final test results. Pre-test results and final test results are often correlated, i.e., the explainability values provide additional information about which features or parameters are important for a fault prediction or anomaly prediction and should therefore be used for anomaly prediction or component classification.

In a preferred embodiment, the respective final test result for the plurality of components is determined based on a machine learning algorithm. The machine learning algorithm preferably predicts the respective final test results for a particular component by regression based on the respective pre-test results. In particular, when applying the method according to the disclosure in the area of semiconductor or chip manufacturing, a preferred algorithm for mapping pre-test results to final test results may be applied by linking the pre-test based anomaly scores and the explainability values to the final test results.

In a preferred embodiment, optimizing the detection threshold comprises evaluating a ROC curve to each of the plurality of test parameters. By using historical information as to whether or not a component has passed or failed a final test and preferably using the respective anomaly score and the respective component-specific explainability values as predictors, a so-called Receiver Operating Characteristic curve (ROC curve) can in particular be determined for each test parameter. These ROC curves can be used to set or optimize the predictive capability or threshold value of the prediction model used. The respective ROC curve preferably indicates how well the anomaly score and the respective explainability values are suitable for predicting final test results. In this case, preferably an area surface under the respective ROC curve is a measure of the quality or predictive accuracy of the prediction of the pre-tests. The larger the “area under the curve” of the respective ROC curve, the better the underlying prediction model. A diagonal of the ROC curve (surface content AUC=0.5) preferably stands for a random selection process. The ROC curves therefore preferably allow for fine tuning of the most appropriate threshold value for anomaly detection (i.e., which point on the ROC curve is desired). An unusually frequent exceedance of the threshold value optimized according to the disclosure preferably serves as an early warning for process problems occurring during component manufacture. A predicted overall yield loss from the pre-test to the final test may preferably be estimated by using the ROC curve(s) and/or applying the limit values optimized by ROC curves. A large deviation from this yield loss can quickly indicate problems in manufacturing between the pre-test and final test (e.g. in packaging).

In a preferred embodiment, a computer-implemented method for determining an anomaly of a component, in particular a semiconductor component and/or a chip and/or a wafer, is disclosed. This method comprises the following steps: providing a prediction model optimized according to the method according to the disclosure according to any embodiment; providing pre-test results determined for a plurality of test parameters for a component; and evaluating the pre-test results by the optimized prediction model to determine whether the component has an anomaly.

According to the disclosure, a computer program with program code is also disclosed to perform at least portions of the method according to the disclosure in one of its embodiments when the computer program is executed on a computer.

According to the disclosure, a computer-readable data carrier with program code of a computer program is also proposed to perform at least portions of the method according to the disclosure in one of its embodiments when the computer program is executed on a computer.

The described embodiments and developments can be combined with one another as desired.

Further possible embodiments, developments, and implementations of the disclosure also include not explicitly mentioned combinations of features of the disclosure described above or below with respect to exemplary embodiments.

### BRIEF DESCRIPTION OF THE DRAWINGS

The accompanying drawings are intended to provide a better understanding of the embodiments of the disclosure. The drawings illustrate embodiments and, in connection with the description, serve to explain principles and concepts of the disclosure.

Further embodiments and many of the specified advantages will emerge with reference to the drawings. The elements shown in the drawings are not necessarily drawn to scale with respect to one another.

The figures show:

FIG. 1 a schematic flow chart of a method according to the disclosure;

FIG. 2 a schematic block diagram of the method according to the disclosure;

FIG. 3 a schematic representation of a visualization of anomaly results determined according to the method according to the disclosure; and

FIG. 4 different ROC plots.

In the figures shown in the drawings, identical reference signs denote identical or functionally identical elements, parts, or components, unless stated otherwise.

### DETAILED DESCRIPTION

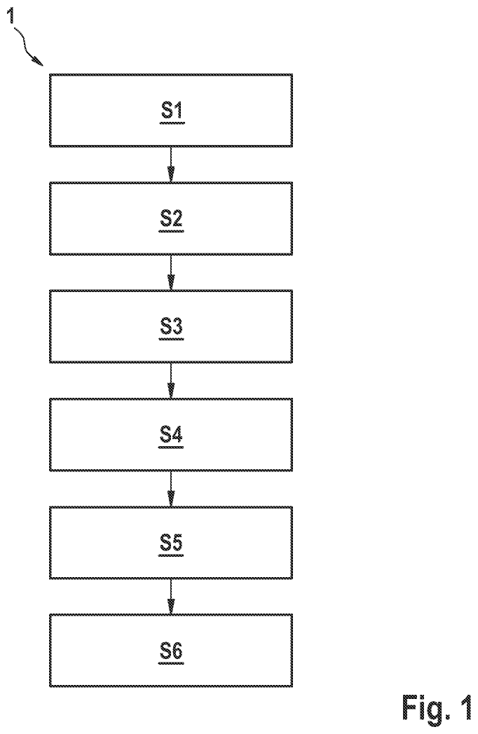

FIG. 1 shows a schematic flow chart of a computer-implemented method for optimizing

a detection threshold of a prediction model used to determine an anomaly of a component, in particular a semiconductor component and/or a chip and/or a wafer. The detection threshold indicates the criterion above which the prediction model classifies a component as anomalous.

In any embodiment, the method may be performed at least in part by a system 1 (schematically indicated in FIG. 1), which may comprise a plurality of components not shown, for example one or more providing devices and/or at least one evaluation and calculation device. It is understood that the providing device may be configured together with the evaluation and computing device, or can be different from it. Furthermore, the system may comprise a storage device and/or an output device and/or a display device and/or an input device.

According to the disclosure, the computer-implemented method comprises at least the following steps:

In a step S1, the prediction model is provided.

In a step S2, a plurality of pre-test results are provided which are determined for a plurality of test parameters for a plurality of components, respectively.

In a step S3, a final test result is provided for each of the plurality of components, wherein the respective final test result indicates whether the respective component has an anomaly in a final test.

In a step S4, an anomaly result is calculated for each of the plurality of components by evaluating the respective pre-test results by the prediction model.

In a step S5, a respective explainability value for each of the plurality of test parameters for each of the plurality of components is calculated by the prediction model.

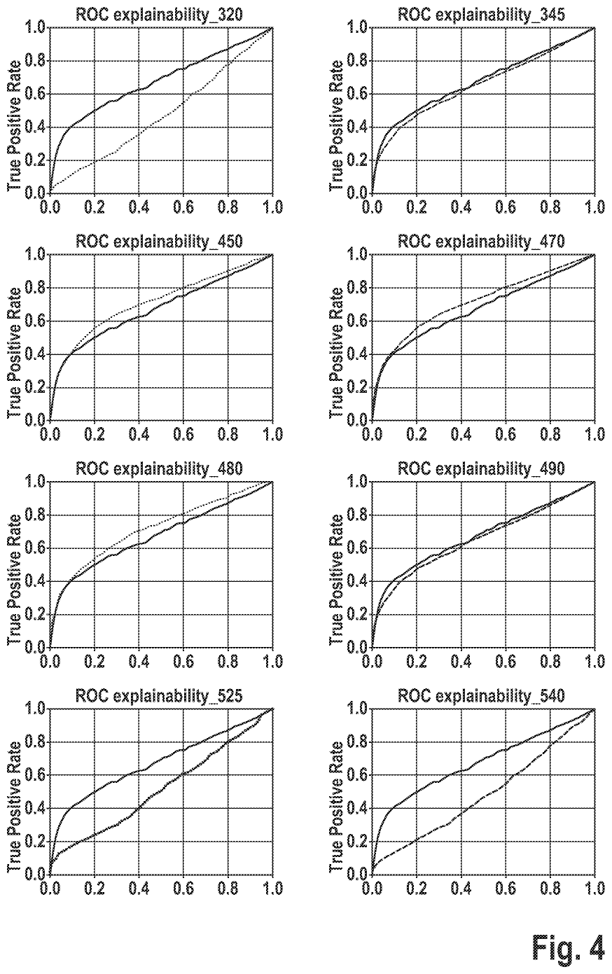

In a step S6, the detection threshold is optimized based on the calculated anomaly results, the calculated explainability values and the final test results provided. Particularly preferably, optimizing the detection threshold comprises evaluating at least one ROC curve for each of the plurality of test parameters for each of the plurality of components. Exemplary ROC curves are shown in FIG. 4.

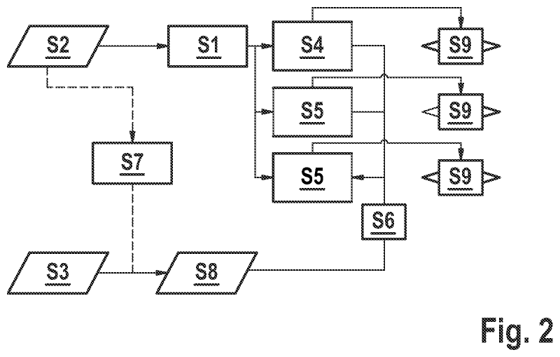

FIG. 2 shows a schematic block diagram of the method according to the disclosure. An exemplary flow of information according to the method is shown herein. Based on the pre-test results and final test results provided in steps S2 and S3, the prediction model provided in step S1 can calculate an anomaly result based on the test parameters per component in steps S4 and S5, as well as a plurality of explainability values for each of the test parameters per component. Since multiple explainability values are calculated, step S5 is displayed twice.

The respective final test results may preferably be algorithmically predicted from the pre-test results using a machine learning algorithm provided in an optional step S7, which is preferably based on a k-regression. However, this is purely optional.

The pre-test results and final test results are combined with each other in an optional step S8, for example by creating ROC curves, in order to optimize or tune the threshold value of the prediction algorithm in step S6.

In an optional step S9, a prediction of the presence of an anomaly of a component can be performed based on the anomaly result and/or based on at least one of the explainability values. Since the prediction can be made based on the anomaly result and/or based on at least one of the explainability values, the optional step S9 is shown multiple times.

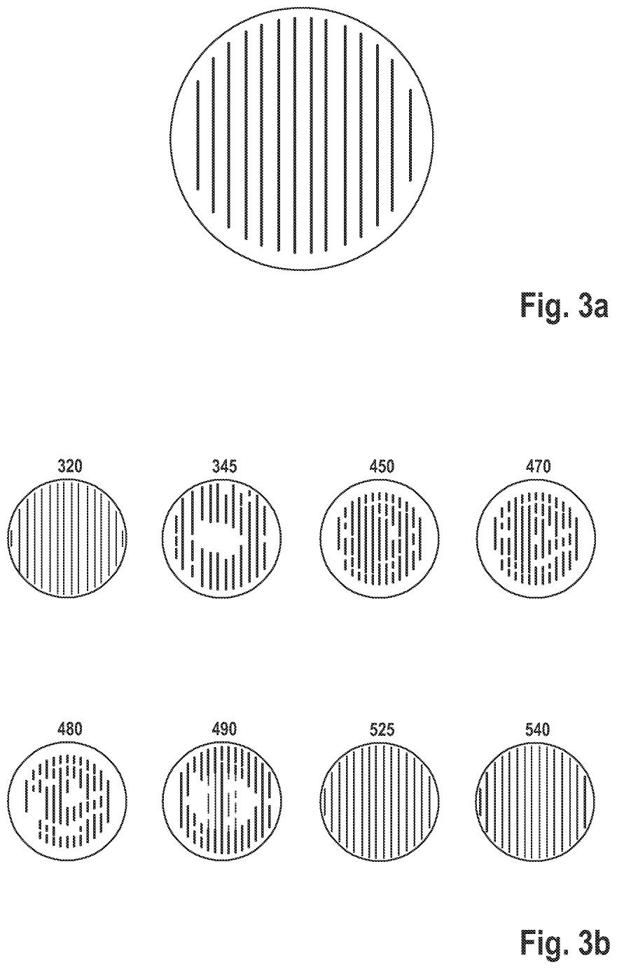

FIG. 3(a) shows an exemplary view of a representation of an anomaly result for a component, in this case a wafer. The different patterns preferably stand for respective threshold value gradations of the anomaly result. The anomaly result is determined based on all test parameters. FIG. 3(b) shows a plurality of examples of explainability values for a plurality of test parameters, in this case 8 test parameters. It can be seen that some of the test parameters have a greater influence on the anomaly evaluation of the component than other test parameters, as the explainability value distribution shows several maxima for these test parameters, for example.

FIG. 4 shows a plurality of ROC curves for different test parameters. A total of 8 ROC curves are plotted for the 8 test parameters shown in FIG. 3. The false-positive rate of the anomaly evaluation or the anomaly classification is shown on the abscissa. A true-positive rate of the anomaly evaluation or of the anomaly classification is shown on the respective ordinate. Based on this real data example, it is easy to see that using certain explainability values (e.g. #470) leads to better results (larger AUC) than the general anomaly score (see solid black curve in the respective graph for comparison). For the explainability value #470, the area under the ROC curve is maximum compared to the other ROC curves. This means that this test parameter has the greatest influence on a positive prediction or a correct prediction as to whether a component has an anomaly or not. For clarity, the ROC curve for test parameter #470 is highlighted with a black box. It can be seen that the anomaly result curve performs worse than the ROC curve for the relevant test parameter with regard to a correct evaluation of whether a component has an anomaly or not. This can be seen because the area content under the ROC curve is larger than the area content under the anomaly result curve. Thus, a prediction based only on the test results for this test parameter would statistically be more accurate than a prediction based on the anomaly score, in which all test parameters are taken into account.

On the other hand, for example, taking the test parameter #540 into account generally leads more often to an incorrect prediction of whether a component has an anomaly or not, as the area under the ROC curve is smaller than the area under the anomaly result curve. It would therefore be better to no longer take this test parameter into account when predicting further components. This selection or sorting is possible according to the disclosure.

The ROC curve (ROC: Receiver Operating Characteristic) also known as the limit value optimization curve or the isosensitivity curve, is preferably a mathematical method for the evaluation and optimization of analysis strategies. The ROC curve is preferably a visual representation of the efficiency dependence on the error rate for different parameter values. The ROC curve may be used to find the best possible value of a parameter, for example, in a dichotomous (semi-)quantitative feature or two class classification problem. A ROC curve near the diagonal indicates a random process: Values near the diagonal mean an equal hit rate and false positive rate, which corresponds to the expected hit frequency of a random process. The ideal ROC curve initially rises vertically (the hit rate (ordinate) is close to 100%, while the error rate (abscissa) initially remains close to 0%); only then does the false positive rate increase. A ROC curve that remains well below the diagonal indicates that the values were interpreted incorrectly.

What is claimed is:

1. A computer-implemented method for optimizing a detection threshold of a prediction model used to determine an anomaly of a semiconductor component and/or a chip and/or a wafer, wherein the detection threshold indicates the criterion above which the prediction model classifies a component as anomalous, the method comprising:
providing the prediction model;
providing a plurality of pre-test results which are determined for a plurality of test parameters for a plurality of components, respectively;
providing a final test result for each of the plurality of components, wherein the respective final test result indicates whether the respective component has an anomaly in a final test;
calculating a respective anomaly result for each of the plurality of components by evaluating the respective pre-test results by the prediction model;
calculating a respective explainability value for each of the plurality of test parameters for each of the plurality of components by the prediction model; and
optimizing the detection threshold based on the calculated anomaly results, the calculated explainability values and the final test results provided.

2. The computer-implemented method according to claim 1, wherein the at least one prediction model comprises an autoencoder model and/or a PCA model.

3. The computer-implemented method according to claim 2, wherein the respective explainability value is determined based on a reconstruction error of the respective test parameter.

4. The computer-implemented method according to claim 1, wherein the optimized detection threshold optimizes predictive accuracy of the prediction model when detecting an anomaly of a component.

5. The computer-implemented method according to claim 1, wherein the pre-test results correlate at least partially and/or by parameter with the final test results.

6. The computer-implemented method according to claim 1, wherein the respective final test result for the plurality of components is determined based on a machine learning algorithm that predicts and/or maps the respective final test results for a particular component by regression based on the respective pre-test results.

7. The computer-implemented method according to claim 1, wherein optimizing the detection threshold comprises evaluating a ROC curve for each of the plurality of test parameters.

8. A computer-implemented method for determining an anomaly of a semiconductor component and/or a chip and/or a wafer, comprising:
providing a prediction model optimized according to the method of claim 1;
providing pre-test results which are determined for a plurality of test parameters for a component; and
evaluating the pre-test results by the optimized prediction model to determine whether the component has an anomaly.

9. A computer program comprising program code to execute at least portions of a method according to claim 1 if the computer program is executed on a computer.

10. A computer-readable data carrier comprising program code of a computer program to execute at least portions of a method according to claim 1 if the computer program is executed on a computer.

11. The computer-implemented method according to claim 1, wherein the at least one prediction model comprises a machine learning algorithm.
